(19) United States
(12) Patent Application Publication
(10) Pub. No.: US 2026/0231424 A1
(43) Pub. Date: Aug. 6, 2026

(54) SEMICONDUCTOR MEMORY DEVICE AND METHOD OF MANUFACTURING THE SEMICONDUCTOR MEMORY DEVICE

(71) Applicant: SK hynix Inc., Icheon-si Gyeonggi-do (KR)

(72) Inventors: Eun Seok CHOI, Icheon-si Gyeonggi-do (KR); Jae Young OH, Icheon-si Gyeonggi-do (KR)

(73) Assignee: SK hynix Inc., Icheon-si Gyeonggi-do (KR)

(21) Appl. No.: 19/635,368

(22) Filed: Mar. 31, 2026

Related U.S. Application Data
(63) Continuation-in-part of application No. 18/494,594, filed on Oct. 25, 2023.

(30) Foreign Application Priority Data
May 2, 2023 (KR) 10-2023-0056902

(51) Int. Cl. H10B 43/35; H10B 41/27; H10B 41/35; H10B 43/27; H10B 80/00; H10W 80/00; H10W 90/00; H10W 90/26

(52) U.S. Cl. CPC H10B 43/35; H10B 41/27; H10B 41/35; H10B 43/27; H10B 80/00; H10W 80/312; H10W 80/327; H10W 90/26; H10W 90/792

(57) ABSTRACT

A semiconductor memory device includes a first gate stacked body including a plurality of interlayer insulating layers and a plurality of conductive patterns that are alternately stacked in a vertical direction; a first source select line and a first insulating pattern that are sequentially disposed on the gate stacked body; a first channel structure extending into the first gate stacked body in the vertical direction, and including a first end protruding from the first gate stacked body; a second gate stacked body over the first gate stacked body including a plurality of interlayer insulating layers and a plurality of conductive patterns that are alternately stacked in a vertical direction; and a second channel structure extending into the second gate stacked body in the vertical direction, wherein the first source select line includes a plurality of conductive layers.

### CROSS-REFERENCE TO RELATED APPLICATION

The present application is a continuation-in-part of U.S. application Ser. No. 18/494,594, filed on Oct. 25, 2023, which claims priority under 35 U.S.C. § 119(a) to Korean patent application number 10-2023-0056902 filed on May 2, 2023, in the Korean Intellectual Property Office, the entire contents of which applications are incorporated herein by reference.

### BACKGROUND

### 1. Technical Field

Various embodiments of the present disclosure generally relate to an electronic device, and more particularly, to a semiconductor memory device having a channel structure and a method of manufacturing the semiconductor memory device.

### 2. Related Art

Semiconductor memory devices are roughly classified into a volatile memory device and a nonvolatile memory device.

Such a nonvolatile memory device has relatively low write and read speeds, but retains data stored therein even when the supply of power is interrupted. Therefore, the nonvolatile memory device is used to store data to be retained regardless of whether power is supplied. Examples of the nonvolatile memory device include a read-only memory (ROM), a mask ROM (MROM), a programmable ROM (PROM), an erasable programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc. The flash memory is classified into a NOR type and a NAND type.

### SUMMARY

An embodiment of the present disclosure may provide for a semiconductor memory device. The semiconductor memory device may include a first gate stacked body including a plurality of interlayer insulating layers and a plurality of conductive patterns that are alternately stacked in a vertical direction; a first source select line and a first insulating pattern that are sequentially disposed on the gate stacked body; a first channel structure extending into the first gate stacked body in the vertical direction, and including a first end protruding from the first gate stacked body; a second gate stacked body over the first gate stacked body including a plurality of interlayer insulating layers and a plurality of conductive patterns that are alternately stacked in a vertical direction; and a second channel structure extending into the second gate stacked body in the vertical direction, wherein the first source select line includes a plurality of conductive layers.

An embodiment of the present disclosure may provide for a semiconductor memory device. The semiconductor memory device may include a first gate stacked body including a plurality of interlayer insulating layers and a plurality of conductive patterns that are alternately stacked in a vertical direction; a first source select line and a first insulating pattern that are sequentially disposed on the gate stacked body; a first channel structure extending into the first gate stacked body in the vertical direction, and including a first end protruding from the first gate stacked body; a second gate stacked body over the first gate stacked body including a plurality of interlayer insulating layers and a plurality of conductive patterns that are alternately stacked in a vertical direction; and a first bonding layer and a second bonding layer, wherein the first and second bonding layers connect the first gate stacked body and the second gate stacked body.

### BRIEF DESCRIPTION OF THE DRAWINGS

FIG. 1 is a block diagram illustrating a semiconductor memory device according to an embodiment of the present disclosure.

FIG. 2 is a circuit diagram for explaining a memory cell array of FIG. 1.

FIG. 3 is a perspective view schematically illustrating a semiconductor memory device according to an embodiment of the present disclosure.

FIG. 4 is a sectional view for explaining the memory cell array of FIG. 1.

FIGS. 5A, 5B, 5C, 5D, 5E, and 5F, 6, 7, and 8A, 8B, 8C, 8D, and 8E are sectional views for explaining a method of manufacturing a semiconductor memory device according to an embodiment of the present disclosure.

FIG. 9 is a block diagram illustrating the configuration of a memory system according to an embodiment of the present disclosure.

FIG. 10 is a diagram illustrating a semiconductor memory device according to some embodiments.

FIG. 11 is a diagram illustrating a semiconductor memory device according to some embodiments.

FIG. 12 is a diagram illustrating a semiconductor memory device according to some embodiments.

FIG. 13 is a diagram illustrating a semiconductor memory device according to some embodiments.

FIG. 14 is a diagram illustrating a semiconductor memory device according to some embodiments.

FIG. 15 is a diagram illustrating a semiconductor memory device according to some embodiments.

FIG. 16 is a diagram illustrating a semiconductor memory device according to some embodiments.

FIG. 17 is a diagram illustrating a semiconductor memory device according to some embodiments.

FIG. 18 is a diagram illustrating a semiconductor memory device according to some embodiments.

FIG. 19 is a diagram illustrating a semiconductor memory device according to some embodiments.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application.

Various embodiments of the present disclosure will now be described in detail with reference to the accompanying drawings so that those skilled in the art can practice the technical spirit of the present disclosure.

Various embodiments of the present disclosure are directed to a semiconductor memory device that is capable of improving electrical characteristics by reducing the resistance of a select line coupled to a select transistor having a vertical channel structure and a method of manufacturing the semiconductor memory device.

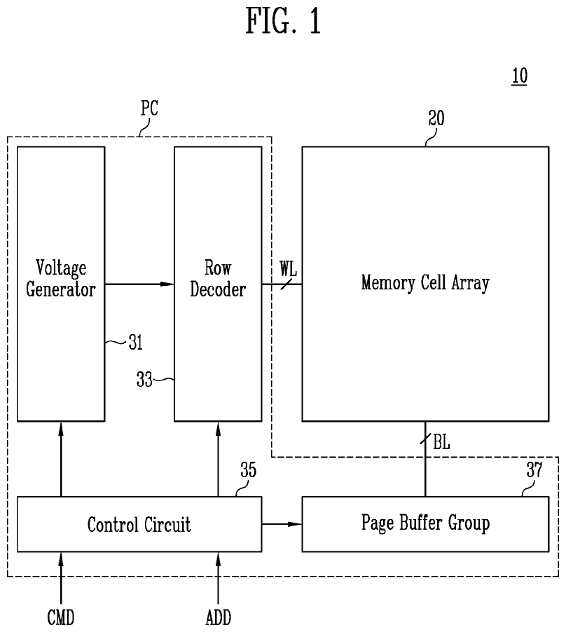

FIG. 1 is a block diagram illustrating a semiconductor memory device according to an embodiment of the present disclosure.

Referring to FIG. 1, a semiconductor memory device 10 includes a peripheral circuit PC and a memory cell array 20.

The peripheral circuit PC may control a program operation of storing data in the memory cell array 20, a read operation of outputting data stored in the memory cell array 20, and an erase operation of erasing data stored in the memory cell array 20.

In an embodiment, the peripheral circuit PC may include a voltage generator 31, a row decoder 33, a control circuit 35, and a page buffer group 37.

The memory cell array 20 may include a plurality of memory blocks. The memory cell array 20 may be coupled to the row decoder 33 through word lines WL, and may be coupled to the page buffer group 37 through bit lines BL.

The control circuit 35 may control the voltage generator 31, the row decoder 33, and the page buffer group 37 in response to a command CMD and an address ADD.

The voltage generator 31 may generate various operating voltages, such as an erase voltage, a ground voltage, a program voltage, a verify voltage, a pass voltage, and a read voltage, which are used for a program operation, a read operation, and an erase operation, under the control of the control circuit 35.

The row decoder 33 may select a memory block under the control of the control circuit 35. The row decoder 33 may apply the operating voltages to the word lines WL coupled to the selected memory block.

The page buffer group 37 may be coupled to the memory cell array 20 through the bit lines BL. The page buffer group 37 may temporarily store data received from an input/output circuit (not illustrated) under the control of the control circuit 35 during a program operation. The page buffer group 37 may sense voltages or currents of the bit lines BL under the control of the control circuit 35 during a read operation or a verify operation. The page buffer group 37 may select the bit lines BL under the control of the control circuit 35.

Structurally, the memory cell array 20 may overlap a part of the peripheral circuit PC.

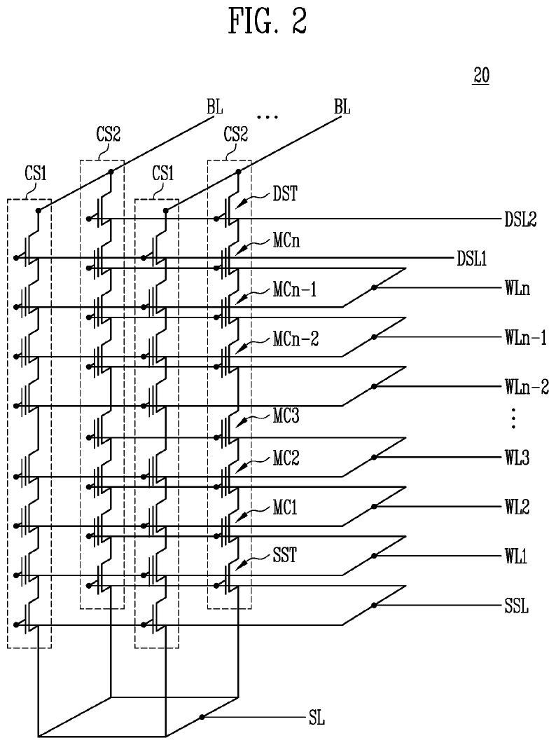

FIG. 2 is a circuit diagram for explaining the memory cell array of FIG. 1.

Referring to FIG. 2, the memory cell array 20 may include a plurality of cell strings CS1 and CS2 coupled between a source line SL and a plurality of bit lines BL. The plurality of cell strings CS1 and CS2 may be coupled in common to a plurality of word lines WL1 to WLn.

Each of the plurality of cell strings CS1 and CS2 may include at least one source select transistor SST coupled to the source line SL, at least one drain select transistor DST coupled to the corresponding bit line BL, and a plurality of memory cells MC1 to MCn coupled in series to each other between the source select transistor SST and the drain select transistor DST.

Gates of the plurality of memory cells MC1 to MCn may be respectively coupled to the plurality of word lines WL1 to WLn stacked to be spaced apart from each other. The plurality of word lines WL1 to WLn may be arranged between a source select line SSL and two or more drain select lines DSL1 and DSL2. The two or more drain select lines DSL1 and DSL2 may be spaced apart from each other at the same level.

A gate of the source select transistor SST may be coupled to the source select line SSL. A gate of the drain select transistor DST may be coupled to a drain select line corresponding to the gate of the drain select transistor DST.

The source line SL may be coupled to a source of the source select transistor SST. A drain of the drain select transistor DST may be coupled to a bit line corresponding to the drain of the drain select transistor DST.

The plurality of cell strings CS1 and CS2 may be divided into string groups coupled to the two or more drain select lines DSL1 and DSL2, respectively. Cell strings coupled to the same word line and the same bit line may be independently controlled by different drain select lines. Further, cell strings coupled to the same drain select line may be independently controlled by different bit lines.

In an embodiment, two or more drain select lines DSL1 and DSL2 may include a first drain select line DSL1 and a second drain select line DSL2. The plurality of cell strings CS1 and CS2 may include first cell strings CS1 of a first string group coupled to the first drain select line DSL1 and second cell strings CS2 of a second string group coupled to the second drain select line DSL2.

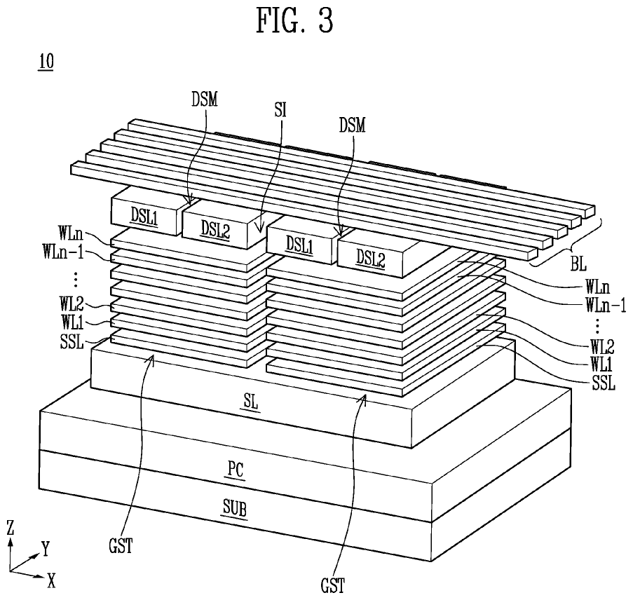

FIG. 3 is a perspective view schematically illustrating a semiconductor memory device according to an embodiment of the present disclosure.

Referring to FIG. 3, a semiconductor memory device 10 may include a peripheral circuit PC arranged on a substrate SUB and gate stacked bodies GST overlapping the peripheral circuit PC.

Each of the gate stacked bodies GST may include a source select line SSL, a plurality of word lines WL1 to WLn, and two or more drain select lines DSL1 and DSL2 separated from each other at the same level by a separation structure DSM.

The source select line SSL and the plurality of word lines WL1 to WLn may extend in a first direction X and a second direction Y, and may be formed in planar shapes parallel to each other on the upper surface of the substrate SUB. The first direction X may be a direction in which the X axis of an XYZ coordinate system faces, and the second direction Y may be a direction in which the Y axis of the XYZ coordinate system faces.

The plurality of word lines WL1 to WLn may be stacked to be spaced apart from each other in a third direction Z. The third direction Z may be a direction in which the Z axis of the XYZ coordinate system faces. The plurality of word lines WL1 to WLn may be arranged between the two or more drain select lines DSL1 and DSL2 and the source select line SSL.

The gate stacked bodies GST may be separated from each other by a slit SI. The separation structure DSM may be formed to be shorter than the slit SI in the third direction Z, and may overlap the plurality of word lines WL1 to WLn.

Each of the separation structure DSM and the slit SI may extend in a linear shape, a zigzag shape, or a wave shape. The width of each of the separation structure DSM and the slit SI may be variously changed depending on the design rule.

The source select line SSL according to an embodiment may be arranged closer to the peripheral circuit PC than the two or more drain select lines DSL1 and DSL2.

The semiconductor memory device 10 may include a source line SL disposed between the gate stacked bodies GST and the peripheral circuit PC and a plurality of bit lines BL spaced farther apart from the peripheral circuit PC than the source line SL. The gate stacked bodies GST may be disposed between the plurality of bit lines BL and the source line SL.

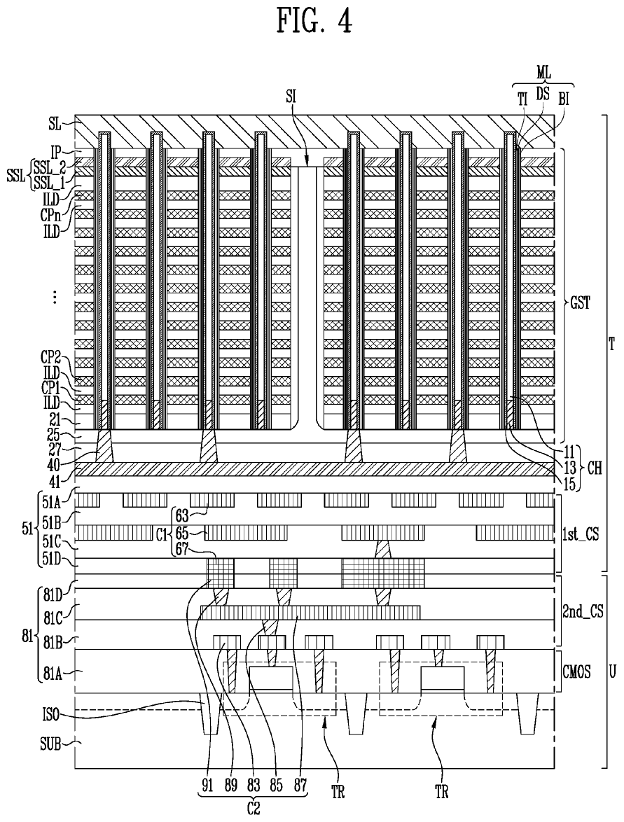

FIG. 4 is a sectional view for explaining the memory cell array of FIG. 1.

Referring to FIG. 4, the memory cell array may be disposed such that a lower structure U and an upper structure T are adhered to each other.

The upper structure T may include gate stacked bodies GST separated from each other by a slit SI, channel structures CH penetrating the gate stacked bodies GST, a memory layer ML extending along the sidewall of each of the channel structures CH, a bit line 41 and a first coupling structure 1st_CS that are disposed under the gate stacked bodies GST, and a source line SL disposed on the gate stacked bodies GST.

Each of the gate stacked bodies GST may include interlayer insulating layers ILD and conductive patterns CP1 to CPn that are alternately stacked in a vertical direction, and a source select line SSL and an insulating pattern IP that are disposed on an interlayer insulating layer ILD disposed in an uppermost portion. For example, the plurality of interlayer insulating layers ILD and the plurality of conductive patterns CP1 to CPn may be defined as a first gate stacked body, and the source select line SSL and the insulating pattern IP may be defined as a second gate stacked body.

Each of the conductive patterns CP1 to CPn may include various conductive materials, such as a doped silicon layer, a metal layer, a metal silicide layer, and a barrier layer, and may include two or more kinds of conductive materials. For example, each of the conductive patterns CP1 to CPn may include tungsten and a titanium nitride (TiN) layer configured to enclose the surface of tungsten. In an embodiment, tungsten is a low-resistance material and is capable of decreasing the resistance of the conductive patterns CP1 to CPn. In an embodiment, the titanium nitride (TiN) layer may be a barrier layer, and may prevent tungsten and the interlayer insulating layers ILD from directly contacting each other.

The first conductive pattern CP1 adjacent to the bit line 41, among the conductive patterns CP1 to CPn, may be used as a drain select line DSL. In other embodiments, conductive patterns of two or more layers, which are adjacent to the bit line 41 and are successively stacked, may be used as drain select lines. The remaining conductive patterns (e.g., CP2 to CPn) other than the conductive patterns used as drain select lines among the conductive patterns CP1 to CPn may be used as the word lines WL1 to WLn described above with reference to FIG. 2. The source select line SSL may include a plurality of conductive layers. The source select line SSL may include at least one metal layer. In an example, the source select line SSL may include a conductive pattern SSL_1 for a first source select line and a conductive pattern SSL_2 for a second source select line. The conductive pattern SSL_1 for the first source select line may be formed of a silicon layer including impurities. The conductive pattern SSL_2 for the second source select line may be formed of a metal layer having a resistance value lower than that of the conductive pattern SSL_1 for the first source select line. The conductive pattern SSL_2 for the second source select line may include a titanium silicide layer.

Each channel structure CH may vertically penetrate the gate stacked body GST, and the first end of the channel structure CH may be formed to protrude higher than the gate stacked body GST. For example, the channel structure CH may extend in a vertical direction within the gate stacked body GST. The channel structure CH may be formed in a hollow type. The channel structure CH may include a core insulating layer 11 configured to fill a central region thereof, a doped semiconductor layer 13 disposed below the core insulating layer 11, and a channel layer 15 configured to enclose the surfaces of the core insulating layer 11 and the doped semiconductor layer 13. The channel layer 15 may be used as a channel area for a cell string corresponding thereto. The channel layer 15 may be made of a semiconductor material. In an embodiment, the channel layer 15 may include a silicon layer. A dopant may be implanted into a portion disposed in an uppermost portion of the channel layer 15, i.e., a portion corresponding to the source select transistor, through an ion implantation process. The channel structure CH may be formed to protrude higher than the insulating pattern IP disposed in an uppermost portion of the gate stacked body GST. For example, the channel layer l5 may be formed such that the height of the uppermost surface of the channel layer 15 is greater than that of the uppermost surface of the insulating pattern IP disposed in an uppermost portion of the gate stacked body GST. In an embodiment, the channel structure CH may extend into the first gate stacked body and the second gate stacked body in the vertical direction, and may include a first end upwardly protruding higher than the second gate stacked body, as shown in FIG. 4.

The memory layer ML may be formed to enclose the surface of the channel structure CH. The memory layer ML may include a tunnel insulating layer TI configured to enclose the channel layer 15 of the channel structure CH, a data storage layer DS configured to enclose the tunnel insulating layer TI, and a blocking insulating layer BI configured to enclose the data storage layer DS. The memory layer ML may extend along the sidewall of the channel structure CH in a vertical direction, and may extend shorter than the channel layer 15. For example, the memory layer ML may be formed to have a height less than that of the channel layer 15. For example, the memory layer ML may be formed between the channel layer 15 and the gate stacked body GST, and may have the same height as the insulating pattern IP disposed in the uppermost portion of the gate stacked body GST.

The source line SL may be disposed on the gate stacked body GST. The source line SL may include at least one conductive layer. The source line SL may be formed to enclose a first end of the channel structure CH protruding higher than the gate stacked body GST. For example, the source line SL may be formed to directly contact the channel layer 15 of the channel structure CH protruding higher than the gate stacked body GST. The source line SL may include at least one of a doped polysilicon layer, titanium nitride (TiN), tungsten (W), and copper (Cu).

The bit line 41 may be disposed below the gate stacked body GST. The bit line 41 may be coupled to respective channel structures CH through contact plugs 40 penetrating a plurality of insulating layers 21, 25, and 27. The bit line 41 may be spaced apart from the substrate SUB by a first insulating structure 51 and a second insulating structure 81.

The first coupling structure 1st_CS may include the first insulating structure 51 and first connection structures C1 formed in the first insulating structure 51. The first connection structures C1 may include various conductive patterns 63, 65, and 67. The first insulating structure 51 may include two or more insulating layers 51A to 51D stacked between the bit line 41 and the second insulating structure 81.

The lower structure U may include a complementary metal oxide semiconductor (CMOS) circuit structure CMOS including a plurality of transistors TR formed on the substrate SUB and a second coupling structure 2nd_CS formed on the CMOS circuit structure CMOS. The plurality of transistors TR may be spaced apart from each other by isolation structures ISO.

The second coupling structure 2nd_CS may include the second insulating structure 81 formed on the substrate SUB and second connection structures C2 formed in the second insulating structure 81. Each of the second connection structures C2 may include various conductive patterns 83, 85, 87, 89, and 91 that are embedded in the second insulating structure 81. The second insulating structure 81 may include two or more insulating layers 81A to 81D that are sequentially stacked.

The upper structure T and the lower structure U may have a structure in which they are adhered to each other through a bonding structure. For example, exposed conductive patterns 67 of the first coupling structure 1st_CS of the upper structure T and exposed conductive patterns 91 of the second coupling structure 2nd_CS of the lower structure U may be disposed to face each other, and may be adhered to each other. The conductive patterns 67 and the conductive patterns 91 may be defined as bonding metal.

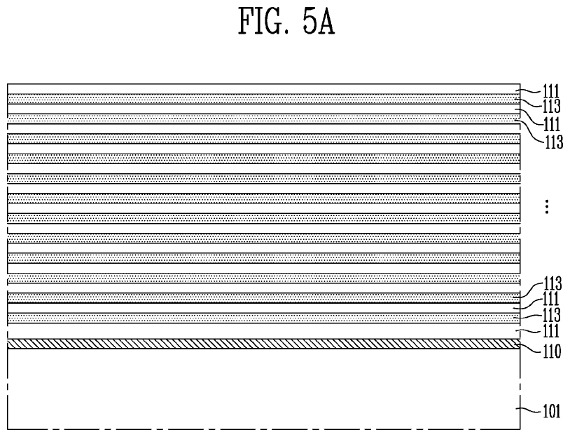

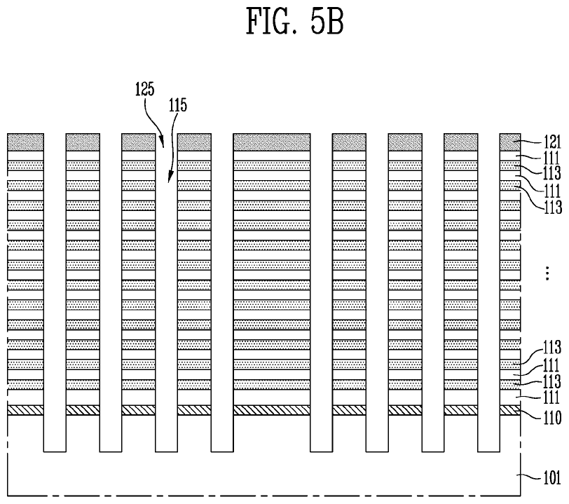

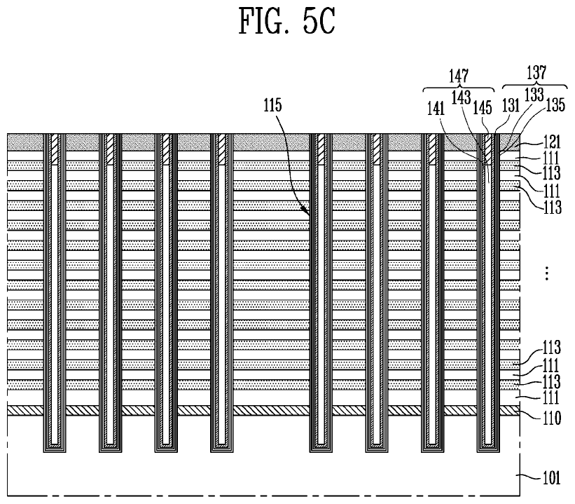

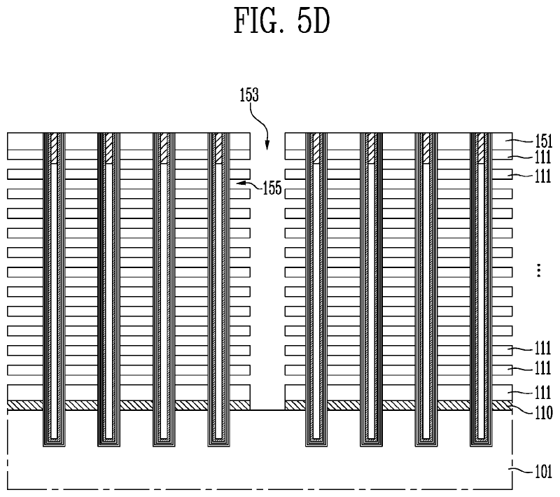

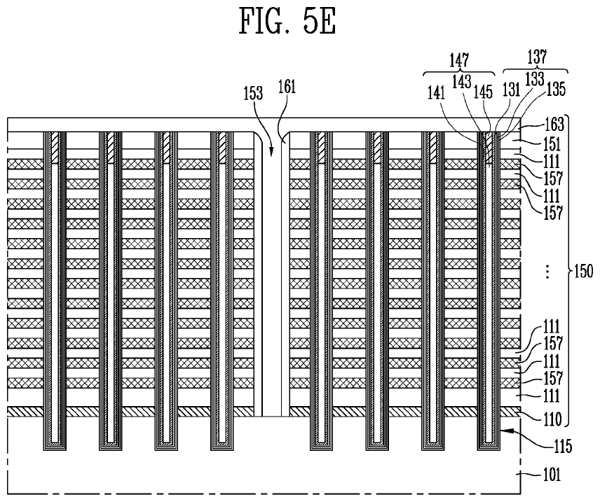

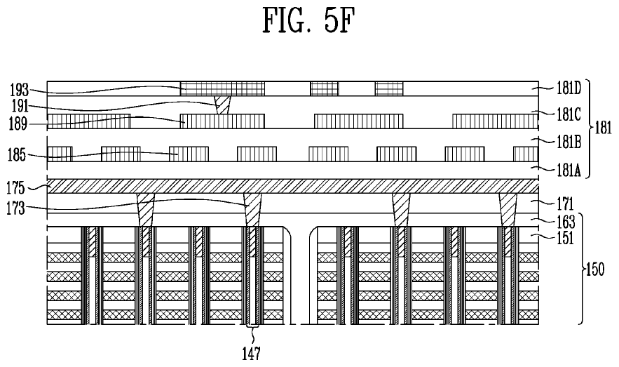

FIGS. 5A to 5F, 6, 7, and 8A to 8E are sectional views for explaining a method of manufacturing a semiconductor memory device according to an embodiment of the present disclosure.

Referring to FIG. 5A, a conductive layer 110 for a first source select line may be formed on a first substrate 101. For example, the first substrate 101 may be a bulk silicon substrate, a silicon-on-insulator substrate, a silicon-germanium substrate, or an epitaxial thin film substrate formed using a selective epitaxial growth method. The conductive layer 110 for the first source select line may be formed by doping the first substrate 101 with impurities to the certain depth of the upper surface of the first substrate 101. That is, the conductive layer 110 for the first source select line may be formed by reforming the upper surface of the first substrate 101 with a conductive material to a certain depth. In an embodiment, the conductive layer 110 for the first source select line may be formed by depositing a conductive polysilicon layer on the first substrate 101.

In an embodiment, first material layers 111 may be made of an insulating material for the interlayer insulating layers ILD, described above with reference to FIG. 4. Second material layers 113 may be made of a material having an etching rate different from that of the first material layers 111. For example, the first material layers 111 may include silicon oxide, and the second material layers 113 may include silicon nitride. Although the following drawings illustrate embodiments in which the first material layers 111 are made of an insulating material and the second material layers 113 are formed of sacrificial layers, the present disclosure is not limited thereto. The material properties of the first material layers 111 and the second material layers 113 may be variously changed. For example, the first material layers 111 may be made of an insulating material for the interlayer insulating layers ILD, described above with reference to FIG. 4, and the second material layers 113 may be made of a conductive material for the conductive patterns CP1 to CPn, described above with reference to FIG. 4.

Referring to FIG. 5B, a first mask pattern 121 including first openings 125 may be formed on a stacked structure of the first material layers 111 and the second material layers 113. Thereafter, channel holes 115 passing through the first material layers 111, the second material layers 113, and the conductive layer 110 for the first source select line may be formed through the first openings 125 of the first mask pattern 121. The channel holes 115 may extend into the first substrate 101 to a certain depth. The channel holes 115 may be formed in various shapes depending on the etching material that is used to form the channel holes 115.

Referring to FIG. 5C, a memory layer 137 and a channel structure 147 may be formed in each of the channel holes 115. The sidewall of the channel structure 147 and the end of the channel structure 147 extending into the first substrate 101 may be enclosed by the memory layer 137.

The step of forming the memory layer 137 may include the step of sequentially stacking a blocking insulating layer 135, a data storage layer 133, and a tunnel insulating layer 131 on the surface of each of the channel holes 115. The blocking insulating layer 135, the data storage layer 133, and the tunnel insulating layer 131 may include the same materials as the blocking insulating layer BI, the data storage layer DS, and the tunnel insulating layer TI, respectively, described above with reference to FIG. 4. The memory layer 137 may be formed in a liner shape, and central regions of the channel holes 115 may be defined by the memory layer 137.

Thereafter, a channel layer 141 may be formed on the surface of the memory layer 137, and then the channel structure 147 may be formed. The channel layer 141 may include a semiconductor layer used as a channel area. For example, the channel layer 141 may include undoped polysilicon.

In an embodiment, the channel layer 141 may be formed in a liner shape, and the central regions of the channel holes 115 may include portions that are not filled with the channel layer 141. When the channel layer 141 is formed in a liner shape, the step of forming the channel structure 147 may include the step of filling the central region of each of the channel holes 115 with a core insulating layer 143 on the channel layer 141, the step of etching a portion of the core insulating layer 143 and defining a recess region in a portion of the central region of each channel hole 115, and the step of filling the recess region with a doped semiconductor layer 145. The core insulating layer 143 may include oxide, and the doped semiconductor layer 145 may include a conductive dopant. The conductive dopant may include an n-type dopant for junctions. The conductive dopant may include a counter-doped p-type dopant.

In other embodiments, the channel layer 141 may be formed to fill the central region of each of the channel holes 115, wherein the core insulating layer 143 and the doped semiconductor layer 145 may be omitted. When the core insulating layer 143 and the doped semiconductor layer 145 are omitted, the step of forming the channel structure 147 may further include the step of doping the conductive dopant into the channel layer 141.

Referring to FIG. 5D, after the first mask pattern 121 of FIG. 5C is removed, a first insulating layer 151 may be formed.

Then, a slit 153 may be formed. The slit 153 may pass through the first insulating layer 151, and may also pass through the stacked structure of the first material layers 111, the second material layers (e.g., 113 of FIG. 5C), and the conductive layer 110 for the first source select line. The slit 153 may correspond to the slit SI illustrated in FIG. 4. Subsequently, the second material layers (e.g., 113 of FIG. 5C) exposed through the slit 153 may be selectively removed, and thus horizontal spaces 155 may be defined. The horizontal spaces 155 may be defined between the first material layers 111 neighboring each other in a vertical direction.

Referring to FIG. 5E, the horizontal spaces 155 illustrated in FIG. 5D may be filled with third material layers 157 through the slit 153. The third material layers 157 may be the conductive patterns CP1 to CPn, described above with reference to FIG. 4. The third material layers 157 may fill the horizontal spaces (e.g., 155 of FIG. 5D) to enclose the channel structure 147 and the memory layer 137.

As described above, a gate stacked body 150 may be formed on the first substrate 101 by replacing the second material layers (e.g., 113 of FIG. 5C) as sacrificial layers with the third material layers 157 as conductive patterns. The gate stacked body 150 may include the conductive layer 110 for the first source select line, as a source select line, and a structure in which the first material layers 111 as interlayer insulating layers and the third material layers 157 as conductive patterns are alternately stacked. The gate stacked body 150 may be penetrated by the channel structure 147, and the channel structure 147 may extend into the first substrate 101. The memory layer 137 may extend from an area between the channel structure 147 and the gate stacked body 150 to an area between the end of the channel structure 147 and the first substrate 101.

Next, a sidewall insulating layer 161 covering the sidewall of the gate stacked body 150 may be formed. Thereafter, a second insulating layer 163 extending to fill the slit 153 and to cover the sidewall insulating layer 161 and the first insulating layer 151 may be formed.

Referring to FIG. 5F, a third insulating layer 171 may be formed on the second insulating layer 163. Thereafter, contact plugs 173 which penetrate the third insulating layer 171 or penetrate both the third insulating layer 171 and the second insulating layer 163 may be formed. The contact plugs 173 may extend to contact the channel structure 147.

Next, a first line array 175 may be formed. The first line array 175 may be a bit line coupled to the contact plugs 173. Thereafter, a first insulating structure 181 covering the first line array 175 may be formed. The first insulating structure 181 may include two or more insulating layers 181A to 181D. First connection structures 185, 189, 191, and 193 may be embedded in the first insulating structure 181, and may be electrically connected to each other through contact plugs (not illustrated).

The first connection structures 185, 189, 191, and 193 may include first bonding metal 193 having a surface exposed to the outside of the first insulating structure 181.

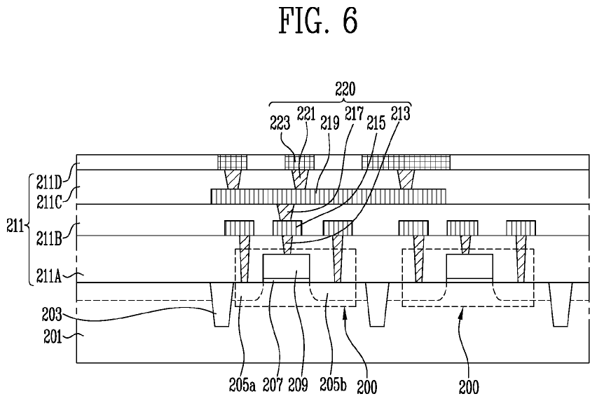

FIG. 6 is a sectional view for explaining the step of forming a CMOS circuit and second connection structures on a second substrate.

Referring to FIG. 6, a plurality of transistors 200 constituting the CMOS circuit may be formed on a second substrate 201.

The second substrate 201 may be a bulk silicon substrate, a silicon-on-insulator substrate, a germanium substrate, a germanium-on-insulator substrate, a silicon-germanium substrate, or an epitaxial layer substrate formed using a selective epitaxial growth method.

The transistors 200 may be formed in respective active areas of the second substrate 201 separated by an isolation layer 203. Each of the transistors 200 may include a gate insulating layer 207 and a gate electrode 209 stacked in the active area corresponding thereto and junctions 205a and 205b formed in active areas disposed on both sides of the gate electrode 209. Each of the junctions 205a and 205b may include a conductive dopant for implementing a transistor corresponding thereto. Each of the junctions 205a and 205b may include at least one of an n-type dopant and a p-type dopant.

After the plurality of transistors 200 are formed, second connection structures 220 coupled to the transistors 200 constituting the CMOS circuit, and a second insulating structure 211 configured to cover the second connection structures 220 and the transistors 200 may be formed.

The second insulating structure 211 may include two or more insulating layers 211A to 211D. The second connection structures 220 may be embedded in the second insulating structure 211. Each of the second connection structures 220 may include a plurality of conductive patterns 213, 215, 217, 219, 221, and 223. The second insulating structure 211 and the second connection structures 220 may be changed in various forms without being limited to the example illustrated in the drawing.

The conductive patterns 213, 215, 217, 219, 221, and 223 included in each of the second connection structures 220 may include second bonding metal 223 having a surface exposed to the outside of the second insulating structure 211.

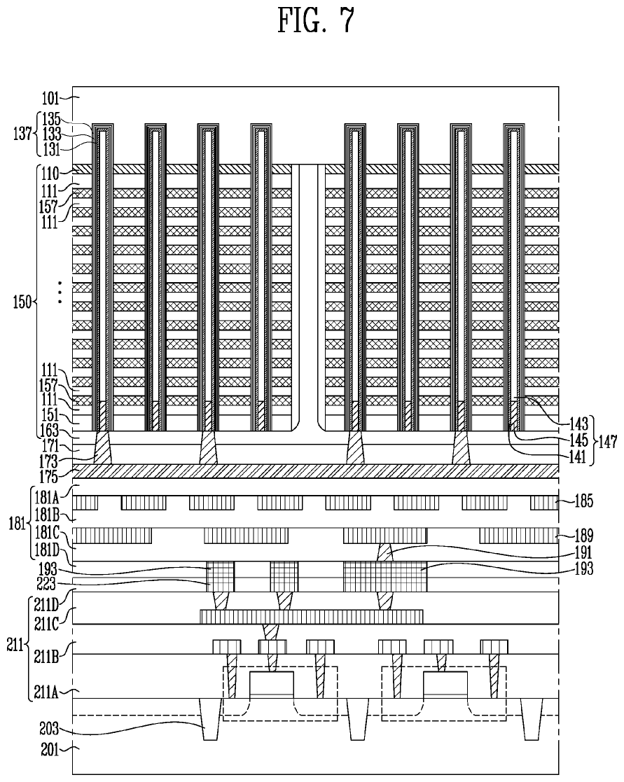

FIG. 7 is a sectional view for explaining the step of adhering the first connection structures and the second connection structures to each other.

Referring to FIG. 7, the first substrate 101 and the second substrate 201 are aligned such that first bonding metal 193 on the first substrate 101 and second bonding metal 223 on the second substrate 201 can contact each other. The first bonding metal 193 and the second bonding metal 223 may contain various types of metal materials, for example, copper.

Thereafter, the first bonding metal 193 and the second bonding metal 223 are adhered to each other. For this, after heat is applied to the first bonding metal 193 and the second bonding metal 223, the first bonding metal 193 and the second bonding metal 223 may be hardened. The present disclosure is not limited thereto, and various processes of coupling the first bonding metal 193 and the second bonding metal 223 to each other may be introduced.

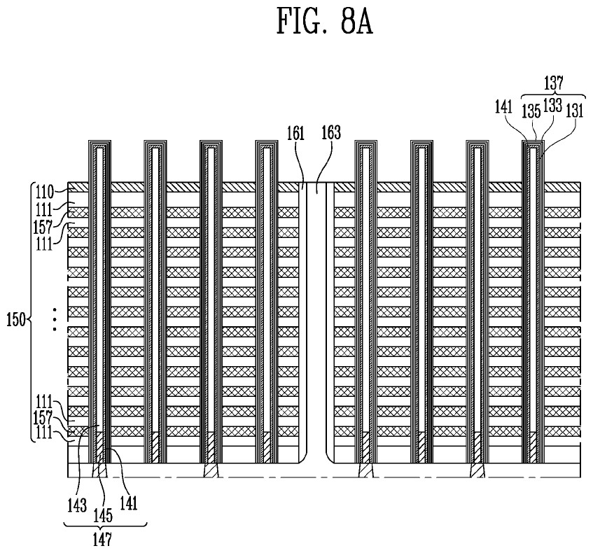

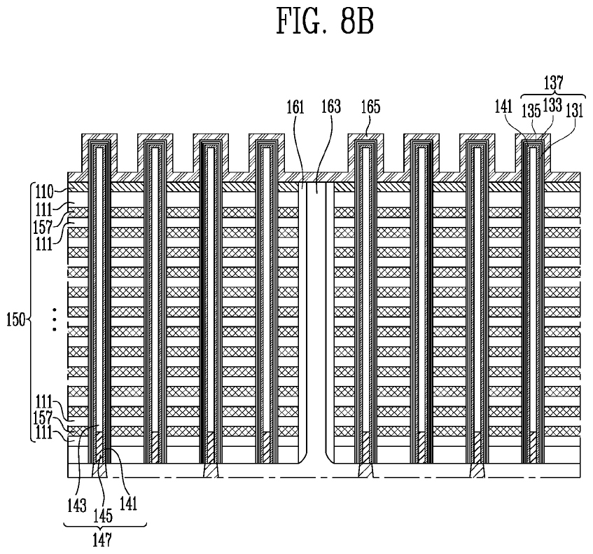

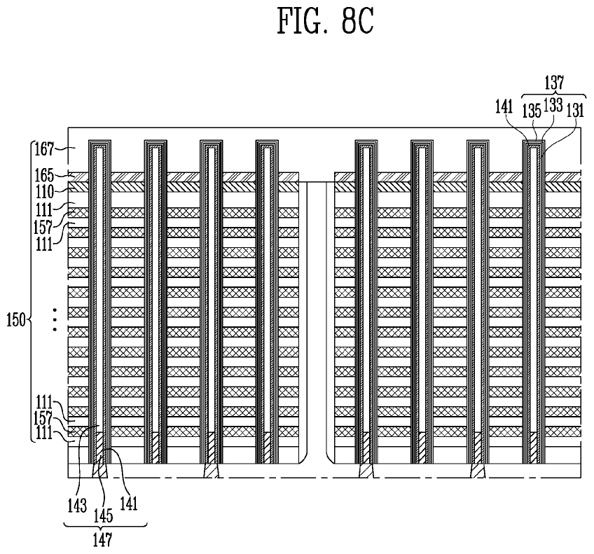

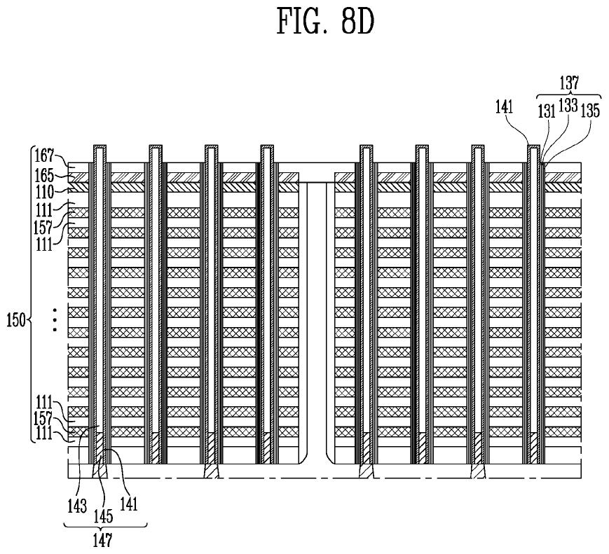

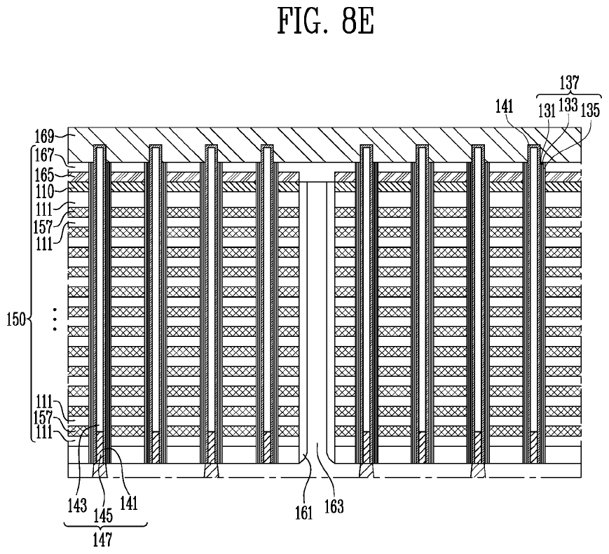

FIGS. 8A to 8E are sectional views for explaining the step of forming a source line structure coupled to a plurality of cell strings on the gate stacked body 150.

Referring to FIG. 8A, the first substrate 101 illustrated in FIG. 7 may be removed. When the first substrate 101 is removed, the memory layer 137 may function as an etching stop layer. Accordingly, the channel structure 147 protruding higher than the gate stacked body 150 may be protected by the memory layer 137. Also, the first substrate 101 may be removed, whereby the conductive layer 110 for the first source select line may be exposed.

Thereafter, a junction area may be formed by performing an ion implantation process and by implanting a dopant into the channel layer 141 used as the channel of a source select transistor.

Referring to FIG. 8B, a conductive layer 165 for a second source select line may be formed along the upper surface of the exposed conductive layer 110 for the first source select line and the surface of the channel structure 147 protruding higher than the gate stacked body 150. The conductive layer 165 for the second source select line may be formed of a material having resistance lower than that of the conductive layer 110 for the first source select line. For example, the conductive layer 165 for the second source select line may be formed of a metal layer. For example, the conductive layer 165 for the second source select line may be formed of a metal silicide layer. For example, the conductive layer 165 for the second source select line may be formed of a titanium silicide layer.

Referring to FIG. 8C, the conductive layer 165 for the second source select line, formed on the protruding channel structure 147, may be etched by performing an etching process, whereby the memory layer 137 enclosing the first end of the channel structure 147 is exposed. For example, the conductive layer 165 for the second source select line may be etched such that the conductive layer 165 for the second source select line remains only on the conductive layer 110 for the first source select line. For example, the conductive layer 165 for the second source select line, formed in the upper surface and sidewall region of the channel structure 147, may be etched such that the first end of the channel structure 147 protrudes higher than the conductive layer 165 for the second source select line. The conductive layer 165 for the second source select line may be defined as being included in the gate stacked body 150.

Thereafter, an insulating layer 167 may be formed on the conductive layer 165 for the second source select line to cover the protruding channel structure 147 and the memory layer 137. The insulating layer 167 may include an oxide layer. The insulating layer 167 may include silicon oxide (SiO_{X}).

Referring to FIG. 8D, the insulating layer 167 may be etched to a certain thickness by performing an etching process. In this way, the memory layer 137 enclosing the first end of the channel structure 147 is exposed. In this case, the insulating layer 167 may remain on the conductive layer 165 for the second source select line to a certain thickness or more.

Thereafter, the channel layer 141 is exposed by removing the exposed memory layer 137 enclosing the first end of the channel structure 147.

Referring to FIG. 8E, a source line 169 may be formed on the exposed channel layer 141 and the insulating layer 167. The source line 169 may directly contact an uppermost portion of the channel layer 141. The source line 169 may include at least one of a doped polysilicon layer, titanium nitride (TiN), tungsten (W), and copper (Cu).

As described above, according to embodiments of the present disclosure, a source select line may be formed of a plurality of conductive layers including a conductive layer for a first source select line and a conductive layer for a second source select line, and at least one layer may be formed of a metal layer having low resistance, thus decreasing the resistance of the source select line.

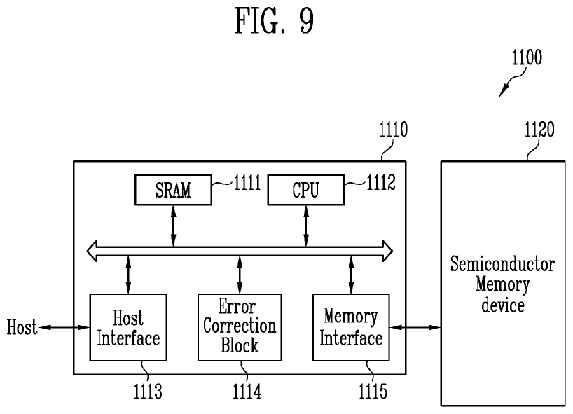

FIG. 9 is a block diagram illustrating the configuration of a memory system according to an embodiment of the present disclosure.

Referring to FIG. 9, a memory system 1100 includes a semiconductor memory device 1120 and a memory controller 1110.

The semiconductor memory device 1120 may be a multi-chip package composed of a plurality of flash memory chips. The semiconductor memory device 1120 may be the semiconductor memory devices described with reference to FIGS. 1 to 4.

The memory controller 1110 may control the semiconductor memory device 1120 and may include a static random access memory (SRAM) 1111, a central processing unit (CPU) 1112, a host interface 1113, an error correction block 1114, and a memory interface 1115. The SRAM 1111 may be used as a working memory of the CPU 1112, the CPU 1112 may perform overall control operations for data exchange of the memory controller 1110, and the host interface 1113 may be provided with a data exchange protocol of a host coupled to the memory system 1100. Further, the error correction block 1114 may detect and correct an error included in data that is read from the semiconductor memory device 1120, and the memory interface 1115 may interface with the semiconductor memory device 1120. In addition, the memory controller 1110 may further include a read only memory (ROM) or the like that stores code data for interfacing with the host.

The above-described memory system 1100 may be a memory card or a solid state drive (or a solid state disk: SSD) in which the semiconductor memory device 1120 and the memory controller 1110 are combined with each other. For example, when the memory system 1100 is an SSD, the memory controller 1110 may communicate with an external device (e.g., host) through one of various interface protocols, such as a universal serial bus (USB), a multimedia card (MMC), a peripheral component interconnection-express (PCI-E), serial advanced technology attachment (SATA), parallel advanced technology attachment (PATA), a small computer system interface (SCSI), an enhanced small disk interface (ESDI), and Integrated Drive Electronics (IDE).

According to an embodiment of the present disclosure, a conductive pattern for a select line contacting the first end of a vertical channel structure is formed of a dual layer including a silicon layer and a low-resistance metal layer, thus reducing the resistance of the conductive pattern for the select line.

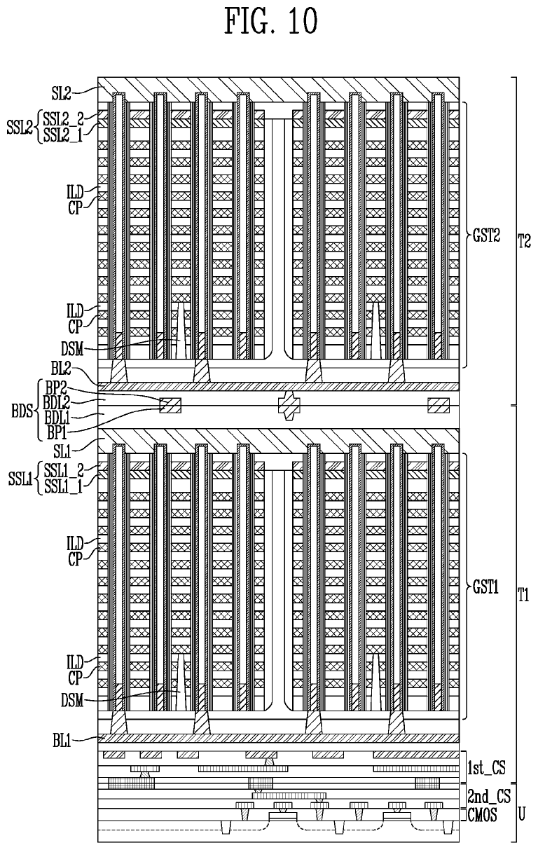

FIG. 10 is a diagram illustrating a semiconductor memory device according to some embodiments. The semiconductor memory device according to FIG. 10 may be similar to the semiconductor memory device according to FIG. 4, except as described below.

Referring to FIG. 10, a semiconductor memory device may include a first upper structure T1 and a second upper structure T2 on the first upper structure T1.

The first upper structure T1 may include a first gate stack body GST1. The first gate stack body GST1 may include interlayer insulating layers ILD and conductive patterns CP. A first bit line BL1 may be provided under the first gate stack body GST1.

A first source select line SSL1 may be provided on the first gate stack body GST1. The first source select line SSL1 may include a plurality of conductive layers. The first source select line SSL1 may include a first conductive layer for the first source select line SSL1_1 and a second conductive layer for the first source select line SSL1_2. The first conductive layer for the first source select line SSL1_1 may include a doped semiconductor material. For example, the first conductive layer for the first source select line SSL1_1 may include doped silicon. The second conductive layer for the first source select line SSL1_2 may include a metal material. The second conductive layer for the first source select line SSL1_2 may include a metal silicide.

A first source line SL1 may be provided over the first source select line SSL1. A first bonding layer BDL1 may be provided over the first source line SL1. The first bonding layer BDL1 may include an insulating material. A first bonding pad BP1 may be provided in the first bonding layer BDL1. The first bonding pad BP1 may include a conductive material. A second upper structure T2 may be provided on the first bonding layer BDL1. The second upper structure T2 may include a second bonding layer BDL2. The second bonding layer BDL2 may include an insulating material. A second bonding pad BP2 may be provided in the second bonding layer BDL2. The second bonding pad BP2 may be in contact with the first bonding pad BP1. The second bonding pad BP2 may include a conductive material. The first and second bonding pads BP1, BP2 may be bonded to each other. The first and second bonding layers BDL1, BDL2 may be bonded to each other. The first and second bonding layers BDL1, BDL2 may be bonded to each other without a boundary, forming a single structure. The first and second bonding pads BP1, BP2 may be bonded to each other without a boundary, forming a single structure. The first and second bonding layers BDL1, BDL2 and the first and second bonding pads BP1, BP2 may define a bonding structure BDS.

The second upper structure T2 may include a second gate stack body GST2. The first and second gate stacks GST1, GST2 may have similar shapes. The second gate stack body GST2 may include conductive patterns CP and interlayer insulating layers ILD.

The bonding structure BDS may be disposed between the first and second gate stacks GST1, GST2. The bonding structure BDS may connect the first and second gate stacks GST1, GST2. A second bit line BL2 may be provided between the second gate stack body GST2 and the bonding structure BDS.

A second source select line SSL2 may be provided on the second gate stack body GST2. The second source select line SSL2 may include a plurality of conductive layers. The second source select line SSL2 may include a first conductive layer for the second source select line SSL2_1 and a second conductive layer for the second source select line SSL2_2. The first conductive layer for the second source select line SSL2_1 may include a doped semiconductor material. The second conductive layer for the second source select line SSL2_2 may include a metal material. The second conductive layer for the second source select line SSL2_2 may include a metal silicide. A second source line SL2 may be provided on the second source selection line SSL2.

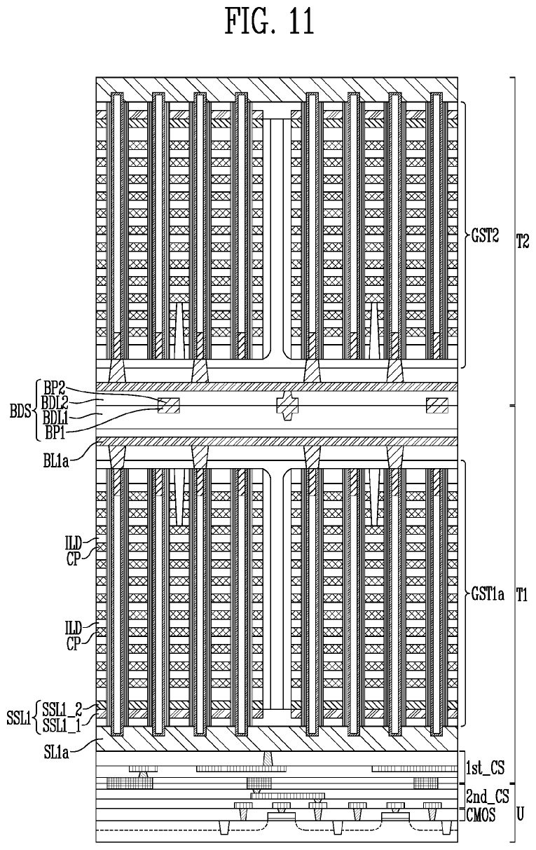

FIG. 11 is a diagram illustrating a semiconductor memory device according to some embodiments. The semiconductor memory device according to FIG. 11 may be similar to the semiconductor memory device according to FIG. 10, except as described below.

Referring to FIG. 11, a first source line SL1a may be provided. A first gate stack body GST1a may be provided on the first source line SL1a. The first source line SL1a may be disposed between the first gate stack body GST1a and the first connection structure 1st_CS.

The first gate stack body GST1 may have a shape similar to the first gate stack body GST1 of the semiconductor memory device according to FIG. 10, flipped upside down. A first bit line BL1a may be provided on the first gate stack body GST1a. A first bit line BL1a may be disposed between a first gate stack body GST1a and a bonding structure BDS.

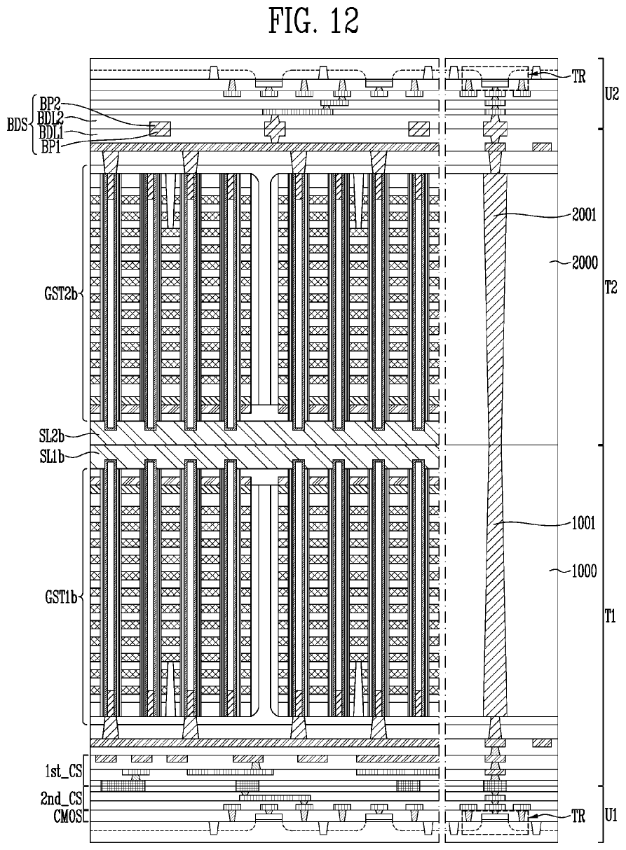

FIG. 12 is a diagram illustrating a semiconductor memory device according to some embodiments. The semiconductor memory device according to FIG. 12 may be similar to the semiconductor memory device according to FIG. 10, except as described below.

Referring to FIG. 12, a first peripheral structure U1 may be provided under the first upper structure T1. A second peripheral structure U2 may be provided above the second upper structure T2. The first peripheral structure U1 may be similar to the lower structure U of the semiconductor memory device according to FIG. 10. The second peripheral structure U2 may have a shape similar to the first peripheral structure U1, flipped upside down.

The first upper structure T1 may include a first gate stack body GST1b and a first source line SL1b above the first gate stack body GST1b. The second upper structure T2 may include a second source line SL2b and a second gate stack GST2b over the second source line SL2b. The first source line SL1b and the second source line SL2b may be in contact with each other. Each of the first and second source lines SL1b, SL2b may include a conductive material. For example, each of the first and second source lines SL1b, SL2b may include doped polysilicon. The first and second source lines SL1b, SL2b may be bonded to each other.

A first connection insulating layer 1000 and a second connection insulating layer 2000 may be provided on one side of the first gate structure GST1b and the second gate structure GST2b. Each of the first and second connection insulating layers 1000, 2000 may include an insulating material. For example, each of the first and second connection insulating layers 1000, 2000 may include an oxide. A first connection contact 1001 penetrating the first connection insulating layer 1000 may be provided. A second connection contact 2001 penetrating the second connection insulating layer 2000 may be provided. The first and second connection contacts 1001, 2001 may be connected to each other. The first and second connection contacts 1001, 2001 may connect the first peripheral structure U1 and the second peripheral structure U2.

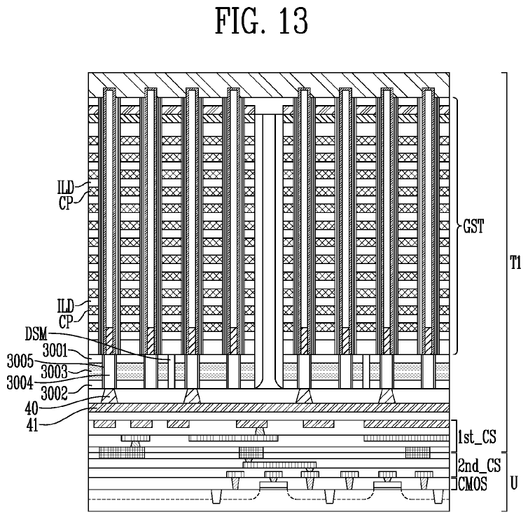

FIG. 13 is a diagram illustrating a semiconductor memory device according to some embodiments. The semiconductor memory device according to FIG. 13 may be similar to the semiconductor memory device according to FIG. 4, except as described below.

Referring to FIG. 13, a first lower insulating layer 3001, a second lower insulating layer 3002, a lower conductive layer 3003 between the first and second lower insulating layers 3001, 3002, a lower channel layer 3004 penetrating the lower conductive layer 3003, and a lower gate insulating layer 3005 surrounding the lower channel layer may be provided under the gate stack GST.

The lower channel layer 3004 may include a semiconductor material. The lower channel layer 3004 may be connected to the bit line 41 through the contact plug 40. The lower channel layer 3004 may be spaced apart from the lower conductive layer 3003 by a lower gate insulating layer 3005. The lower conductive layer 3003, the lower gate insulating layer 3005, and the lower channel layer 3004 may define a drain select transistor. For example, the lower conductive layer 3003 may include a drain select line. The isolation structure DSM may penetrate the lower conductive layer 3003.

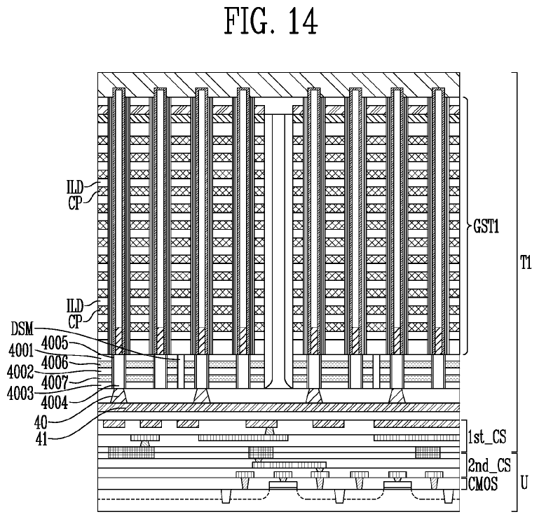

FIG. 14 is a diagram illustrating a semiconductor memory device according to some embodiments. The semiconductor memory device according to FIG. 14 may be similar to the semiconductor memory device according to FIG. 13, except as described below.

Referring to FIG. 14, a first lower insulating layer 4001, a second lower insulating layer 4002, a third lower insulating layer 4003, a lower channel layer 4004, a lower gate insulating layer 4005, a first lower conductive layer 4006, and a second lower conductive layer 4007 may be provided under the first gate stack GST1.

The second lower insulating layer 4002 may be disposed between the first lower insulating layer 4001 and the third lower insulating layer 4003. The first lower conductive layer 4006 may be disposed between the first lower insulating layer 4001 and the second lower insulating layer 4002. A second lower conductive layer 4007 may be disposed between the second lower insulating layer 4002 and the third lower insulating layer 4003. Each of the first lower conductive layer 4006 and the second lower conductive layer 4007 may include a drain select line. A separation structure DSM may penetrate each of the first lower conductive layer 4006 and the second lower conductive layer 4007.

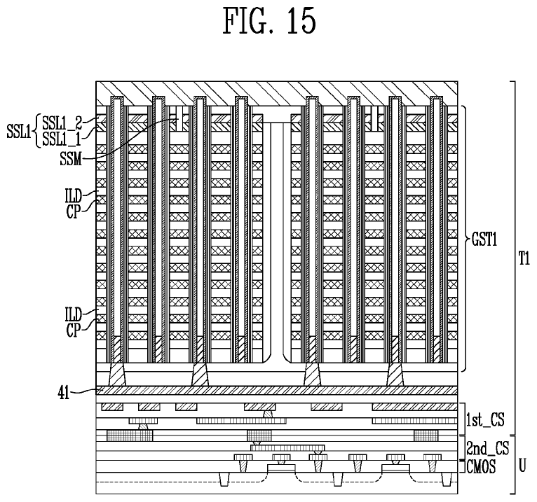

FIG. 15 is a diagram illustrating a semiconductor memory device according to some embodiments. The semiconductor memory device according to FIG. 15 may be similar to the semiconductor memory device according to FIG. 4, except as described below.

Referring to FIG. 15, a separation insulating pattern SSM penetrates the source select line SSL may be provided. The separation insulating pattern SSM may penetrate the first source select line conductive layer SSL_1 and the second source select line conductive layer SSL_2. The separation insulating pattern SSM may include an insulating material. The separation insulating pattern SSM may extend horizontally to separate the source selection line SSL into a plurality of source selection lines SSL. In some embodiments, the separation insulating pattern SSM may extend in a direction intersecting the bit line 41.

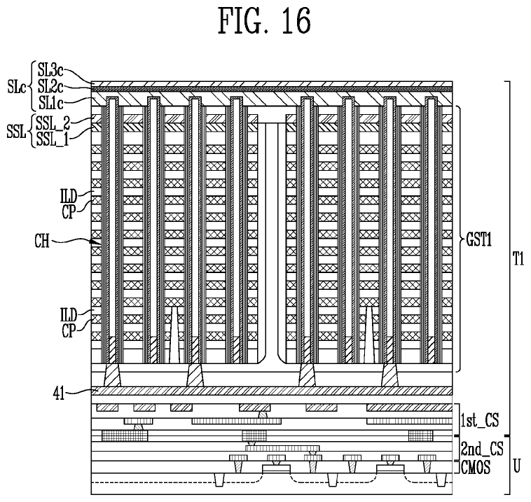

FIG. 16 is a diagram illustrating a semiconductor memory device according to some embodiments. The semiconductor memory device according to FIG. 16 may be similar to the semiconductor memory device according to FIG. 4, except as described below.

Referring to FIG. 16, the semiconductor memory device may include a source line SLc. The source line SLc may include a first source layer SL1c, a second source layer SL2c on the first source layer SL1c, and a third source layer SL3c on the second source layer SL2c. The first to third source layers SL1c-SL3c may include a conductive material. The first source layer SL1c may include, for example, doped polysilicon. The second source layer SL2c may include, for example, a metal silicide (for example, WSi). The third source layer SL3c may include, for example, a metal nitride (for example, TiN). Manufacturing the semiconductor memory device according to FIG. 16 may include forming a first source layer SL1c on exposed upper portion of the channel pattern CH, forming a second source layer SL2c on the first source layer SL1c, and forming a third source layer SL3c on the second source layer SL2c.

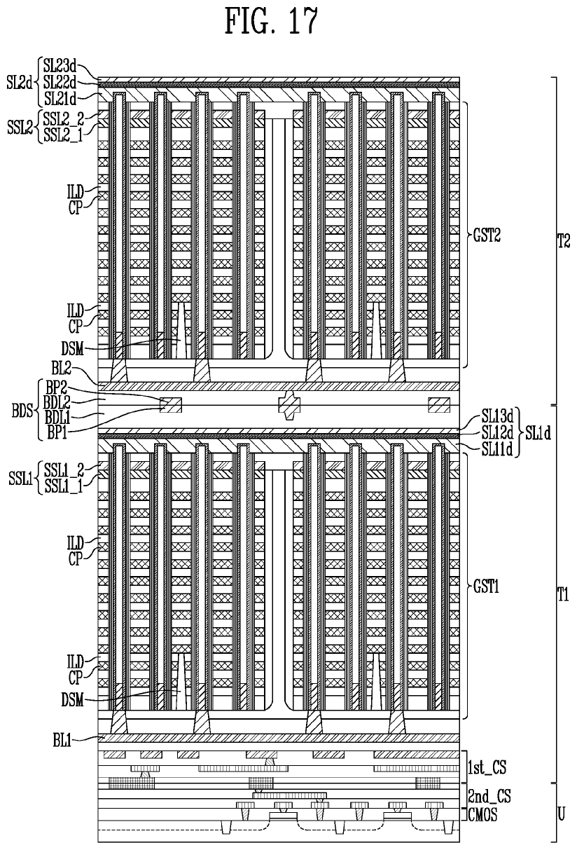

FIG. 17 is a diagram illustrating a semiconductor memory device according to some embodiments. The semiconductor memory device according to FIG. 17 may be similar to the semiconductor memory device according to FIG. 10, except as described below.

Referring to FIG. 17, the first upper structure T1 may include a first source line SL1d. The first source line SL1d may include a first source layer SL11d, a second source layer SL12d on the first source layer SL11d, and a third source layer SL13d on the second source layer SL12d. The second upper structure T2 may include a second source line SL2d. The second source line SL2d may include a first source layer SL21d, a second source layer SL22d on the first source layer SL21d, and a third source layer SL23d on the second source layer SL22d.

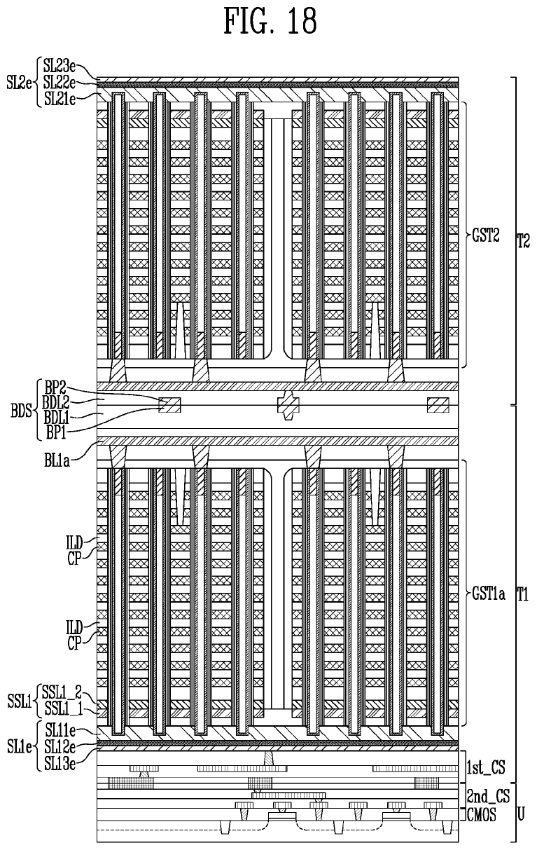

FIG. 18 is a diagram illustrating a semiconductor memory device according to some embodiments. The semiconductor memory device according to FIG. 18 may be similar to the semiconductor memory device according to FIG. 11, except as described below.

Referring to FIG. 18, the first source line SL1e may include a third source layer SL13e, a second source layer SL12e on the third source layer SL13e, and a first source layer SL11e on the second source layer SL12e. The first source layer SL11e may include doped polysilicon. The second source layer SL12e may include metal silicide. The third source layer SL13e may include metal nitride.

The second source line SL2e may include a first source layer SL21e, a second source layer SL22e on the first source layer SL21e, and a third source layer SL23e on the second source layer SL22e.

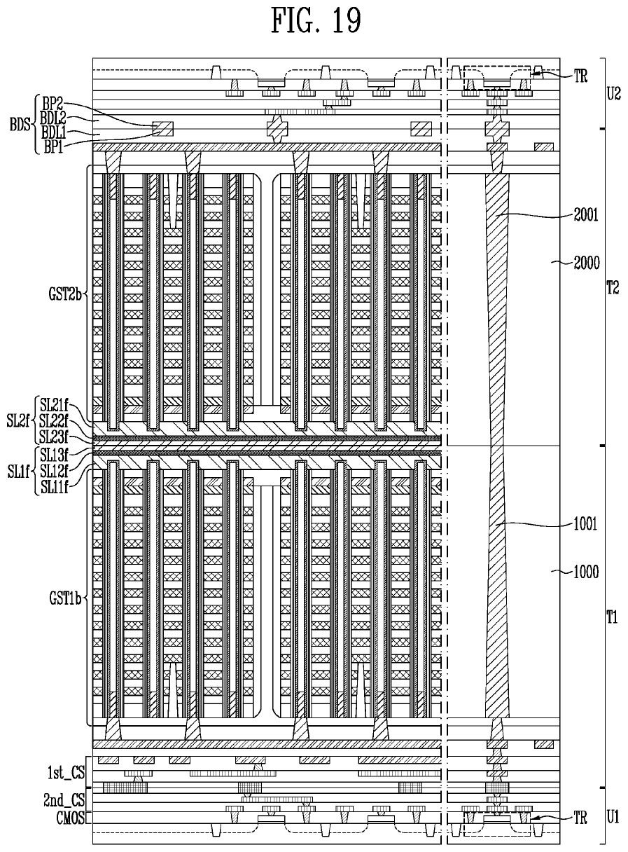

FIG. 19 is a diagram illustrating a semiconductor memory device according to some embodiments. The semiconductor memory device according to FIG. 19 may be similar to the semiconductor memory device according to FIG. 12, except as described below.

Referring to FIG. 19, the first source line SL1f may include a first source layer SL11f, a second source layer SL12f on the first source layer SL11f, and a third source layer SL13f on the second source layer SL12f. The second source line SL2f may include a third source layer SL23f, a second source layer SL22f on the third source layer SL23f, and a first source layer SL21f on the second source layer SL22f.

The first source line SL1f and the second source line SL2f may be bonded to each other. The third source layer SL13f of the first source line SL1f and the third source layer SL23f of the second source line SL2f may be bonded to each other.

While the embodiments of the present disclosure have been disclosed for illustrative purposes, those skilled in the art will appreciate that various modifications, additions and substitutions are possible. Therefore, the scope of the present disclosure must be defined by the appended claims and equivalents of the claims rather than by the above description preceding them.

What is claimed is:

1. A semiconductor memory device, comprising:
a first gate stacked body including a plurality of interlayer insulating layers and a plurality of conductive patterns that are alternately stacked in a vertical direction;
a first source select line and a first insulating pattern that are sequentially disposed on the gate stacked body;
a first channel structure extending into the first gate stacked body in the vertical direction, and including a first end protruding from the first gate stacked body;
a second gate stacked body over the first gate stacked body including a plurality of interlayer insulating layers and a plurality of conductive patterns that are alternately stacked in a vertical direction; and
a second channel structure extending into the second gate stacked body in the vertical direction,
wherein the first source select line includes a plurality of conductive layers.

2. The semiconductor memory device according to claim 1, further comprising a second source select line on the second gate stacked body, and
wherein the second source select line includes a plurality of conductive layers.

3. The semiconductor memory device according to claim 1, wherein the plurality of conductive layers includes a metal layer.

4. The semiconductor memory device according to claim 3, wherein the plurality of conductive layers further includes a doped silicon layer.

5. The semiconductor memory device according to claim 1, further comprising a first bonding layer between the first gate stack body and the second gate stack body, and a second bonding layer between the first gate stack body and the second gate stack body.

6. The semiconductor memory device according to claim 5, wherein the first and second bonding layers are integrated with each other.

7. The semiconductor memory device according to claim 5, further comprising a first bonding pad in the first bonding layer and a second bonding pad in the second bonding layer.

8. The semiconductor memory device according to claim 7, the first and second bonding pads are integrated with each other.

9. The semiconductor memory device according to claim 1, further comprising, a memory layer surrounds a sidewall of the first channel structure.

10. The semiconductor memory device according to claim 1, further comprising, a first source line on the first insulating pattern.

11. The semiconductor memory device according to claim 10, further comprising:
a second source select line on the second gate stack body; and
a second source line over the second source select line.

12. A semiconductor memory device, comprising:
a first gate stacked body including a plurality of interlayer insulating layers and a plurality of conductive patterns that are alternately stacked in a vertical direction;
a first source select line and a first insulating pattern that are sequentially disposed on the gate stacked body;
a first channel structure extending into the first gate stacked body in the vertical direction, and including a first end protruding from the first gate stacked body;
a second gate stacked body over the first gate stacked body including a plurality of interlayer insulating layers and a plurality of conductive patterns that are alternately stacked in a vertical direction; and
a first bonding layer and a second bonding layer,
wherein the first and second bonding layers connect the first gate stacked body and the second gate stacked body.

13. The semiconductor memory device according to claim 12, wherein the first and second bonding layers are bonded with each other.

14. The semiconductor memory device according to claim 12, further comprising the first bonding pad in the first bonding layer and the second bonding pad in the second bonding layer.

15. The semiconductor memory device according to claim 12, wherein the first source select line includes a first conductive line for the first source select line and a second conductive line for the first source select line.

16. The semiconductor memory device according to claim 15, wherein the first conductive line for the first source line is disposed between the second conductive line for the first source line, and the first gate stack structure.

17. The semiconductor memory device according to claim 16, wherein the first conductive line for the first source line includes a doped silicon material.

18. The semiconductor memory device according to claim 17, wherein the second conductive line for the first source line includes a metal silicide.

19. The semiconductor memory device according to claim 12, further comprise a source line, and
wherein the source line includes a first source layer, a second source layer and a third source layer.

20. The semiconductor memory device according to claim 19, wherein the first source layer includes a doped semiconductor material,
wherein the second source layer includes a metal silicide, and
wherein the third source layer includes a metal nitride.
